(19) United States
(12) Patent Application Publication
(10) Pub. No.: US 2002/0063198 A1
(43) Pub. Date: May 30, 2002

(54) Frame shutter for CMOS APS

(76) Inventors: Alexander I. Krymski, Montrose, CA (US); Vladimir Berezin, La Crescenta, CA (US)

Correspondence Address: SCOTT C. HARRIS, Fish & Richardson P.C., Suite 500, 4350 La Jolla Village Drive, San Diego, CA, 92122, US

(21) Appl. No.: 10/040,058

(22) Filed: Oct. 26, 2001

Related U.S. Application Data
(60) Provisional application No. 60/243,899, filed on Oct. 26, 2000.

(51) Int. Cl. H01L 27/00

(52) U.S. Cl. 250/208.1

(57) ABSTRACT

A CMOS Active Pixel Sensor (APS) uses a pinned photodiode as a photoreceptor and negative-channel metal-oxide semiconductor (NMOS) transistors in the sample and hold and reset circuits of the frame shutter. The pinned photodiode increases the quantum efficiency and reduces the dark current. The NMOS transistors in the frame shutter increase the fill factor and reduce the pixel pitch.

### CROSS-REFERENCE TO RELATED APPLICATIONS

This invention claims priority under 35 U.S.C. 119/120 from provisional application serial No. 60/243,899 filed Oct. 26, 2000.

### TECHNICAL FIELD

This invention relates to complementary metal oxide semiconductor (CMOS) Active Pixel Sensors (APS), and more particularly to an improved frame-shutter for a CMOS APS.

### BACKGROUND

CMOS active pixel image sensors may be operated using a “rolling” shutter. Such a shutter operates by reading out each row of pixels, and then resetting that individual row, and then rolling to read and then reset the next row of pixels. Each pixel hence gets read and then reset at slightly different times. Hence, each pixel has a slightly different time of integration. Some applications, such as high-speed photography, may require more time consistency than is possible using this approach. Therefore, in these other applications, a frame shutter may be used. In the frame shutter mode, all pixels in the array have substantially identical integration start times and integration stop times.

A typical CMOS Active Pixel Sensor (APS) 100 architecture utilizing a frame shutter is shown in FIG. 1. The APS 100 includes a photoreceptor 105, a frame shutter 110, and an active pixel readout 115. The photoreceptor 105 may comprise, for example, a photogate or a photodiode. The frame shutter 110 includes sample and hold circuits as well as reset circuits. The sample and hold and reset circuits may be implemented using transistors. FIG. 2 illustrates an APS 200 using a photogate 205 as the photoreceptor 105 and a PMOS frame shutter in a N-well 207. The PMOS frame shutter 207 includes PMOS transistors for the sample and hold circuits 210 and reset circuits 215, 220. The N-well pocket has a +V_{dd} potential and insulates floating diffusion from photo=generated electrons. An active pixel readout 230 includes a source follower and row select circuits. The APS 200 architecture may reduce photo-generated charge cross-talk and increase the shutter efficiency. However, a photogate 205 as a photoreceptor has a low quantum efficiency and a relatively large dark current. Also, the N-well insert in the pixel significantly reduces the fill factor and increases the minimum pixel pitch.

### SUMMARY

A CMOS Active Pixel Sensor (APS) uses a pinned photodiode as a photoreceptor and negative-channel metal-oxide semiconductor (NMOS) transistors in the sample and hold and reset circuits of the frame shutter. The pinned photodiode increases the quantum efficiency and reduces the dark current. The NMOS transistors in the frame shutter increases the fill factor and reduces the pixel pitch.

### DESCRIPTION OF DRAWINGS

These and other features and advantages of the invention will become more apparent upon reading the following detailed description and upon reference to the accompanying drawings.

FIG. 1 illustrates a typical CMOS Active Pixel Sensor (APS) architecture utilizing a frame shutter.

FIG. 2 illustrates an APS using a photogate as the photoreceptor and PMOS transistors for the sample and hold circuits and reset circuits.

FIG. 3 illustrates an APS using a pinned photodiode as the photoreceptor.

FIG. 4 illustrates an APS using a photogate as the photoreceptor and NMOS transistors for the sample and hold circuits and reset circuits.

FIG. 5 illustrates an APS using a pinned photodiode as the photoreceptor and PMOS transistors for the sample and hold circuits and reset circuits.

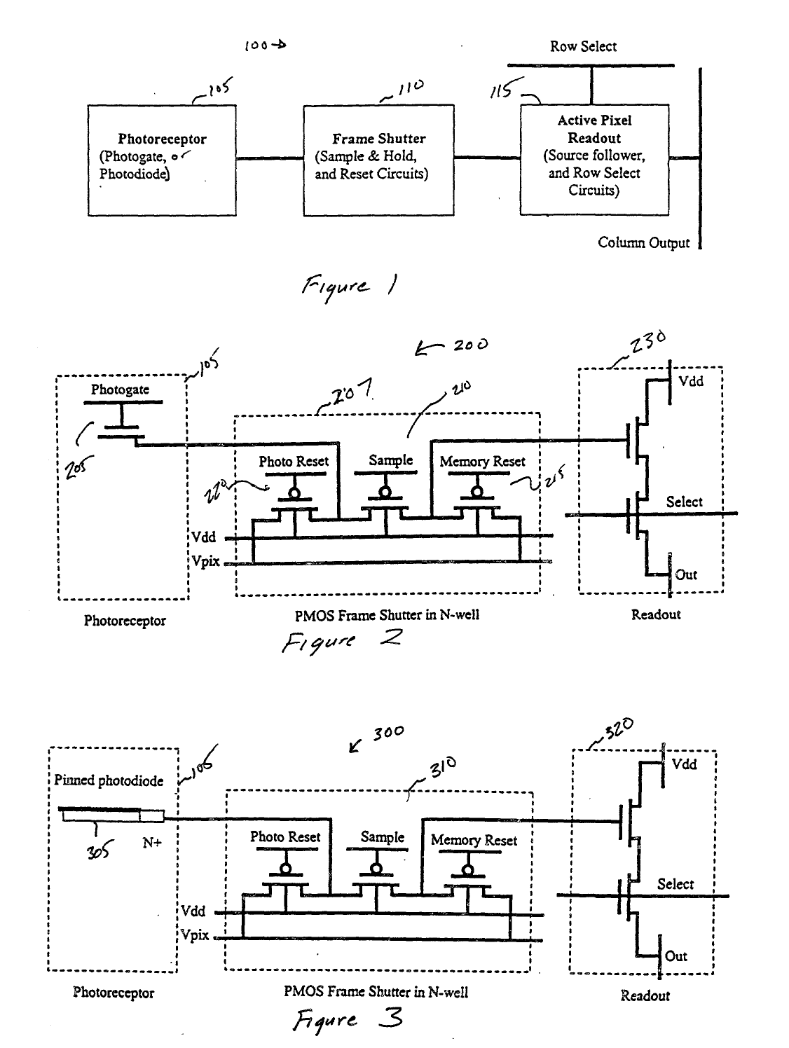

### DETAILED DESCRIPTION

CMOS APS for high-speed machine imaging needs freeze-frame simultaneous electronic shutter. Although the previous architectures reduced the photo-generated cross-talk and increased shutter efficiency, there is still a need to improve the quantum efficiency and decrease the dark current, as well as increasing the fill factor and reducing the pixel pitch.

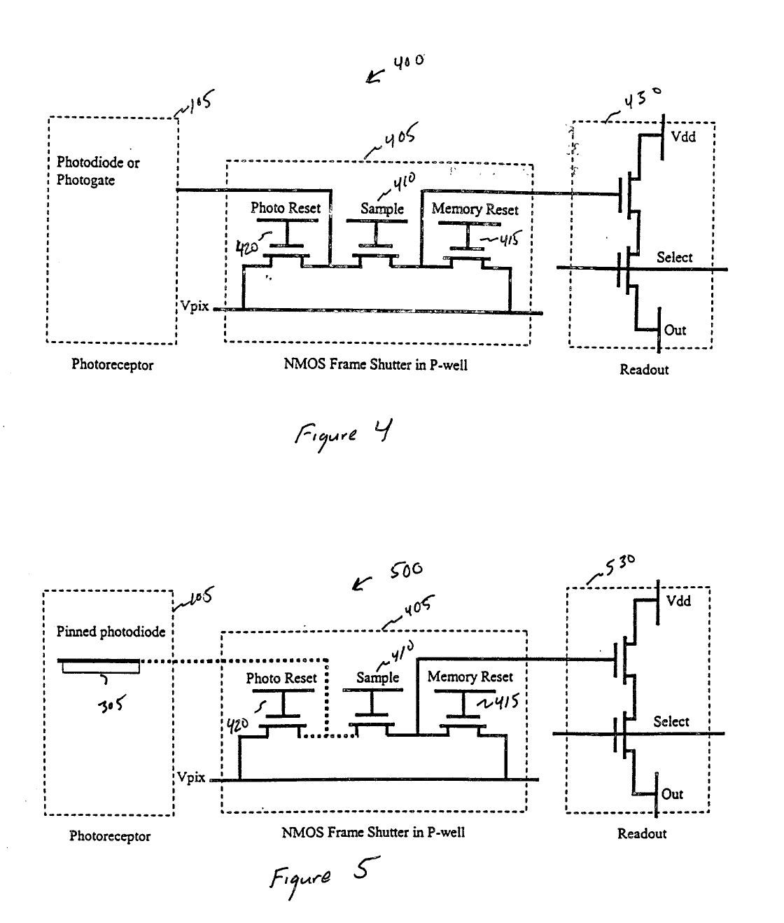

FIG. 3 illustrates an APS 300 using a pinned photodiode 305 as the photoreceptor 105 according to one embodiment of the invention. Pinned photodiodes have been employed within charge coupled devices and have shown advantages in the area of color response for blue light, dark current density and image lag. Thus, using a pinned photodiode 305 as the photoreceptor should increase the quantum efficiency and decrease the dark current. The APS 300 includes the pinned photodiode 305 connected to a PMOS Frame Shutter 310 in a N-well, as well as an active pixel readout circuit 320 This embodiment may be used when quantum efficiency and dark current are concerns.

A second embodiment of the present invention may be used when fill factor and pixel pitch are the primary concerns. FIG. 4 illustrates an APS architecture 400 using a photogate or photodiode as the photoreceptor 105 and NMOS transistors for the sample and hold circuits and reset circuits. A The frame shutter 405 is a NMOS frame shutter in a P-well. NMOS transistors are used for the sample and hold circuits 410 and the reset circuits 415, 420. The N-well insert in a pixel significantly reduces the fill factor and increases the minimum pixel pitch. By replacing the N-well with the P-well, the fill factor is increased and the pixel pitch reduced. An active pixel readout circuit 430 is connected to the frame shutter 405.

A third embodiment of the present invention combines the use of a pinned photodiode as the photoreceptor and the use of NMOS transistors for the sample and hold circuits and reset circuits. FIG. 5 illustrates an APS architecture 500 using a pinned photodiode 305 as the photoreceptor 105 and PMOS transistors for the sample and hold circuits and reset circuits. In this embodiment, the pinned photodiode 305 is connected to the NMOS Frame Shutter 405 in a P-well, as well as an active pixel readout circuit 530. The NMOS transistors are used for the sample and hold circuits 410 and the reset circuits 415, 420. The pinned photodiode 305 as the photoreceptor increases the quantum efficiency and decreases the dark current, while the P-well increases the fill factor and reduces the pixel pitch.

Numerous variations and modifications of the invention will become readily apparent to those skilled in the art. Accordingly, the invention may be embodied in other specific forms without departing from its spirit or essential characteristics.

What is claimed is:

1. An active pixel sensor comprising:
a photoreceptor, wherein the photoreceptor comprises a pinned photodiode;
a frame shutter; and
an active pixel readout.

2. The active pixel sensor of claim 1, wherein the frame shutter is a PMOS frame shutter in a N-well.

3. The active pixel sensor of claim 2, wherein the frame shutter includes sample and hold and reset circuits.

4. The active pixel sensor of claim 3, wherein the sample and hold and reset circuits comprise PMOS transistors.

5. The active pixel sensor of claim 1, wherein the pinned photodiode increases the quantum efficiency.

6. The active pixel sensor of claim 1, wherein the pinned photodiode reduces dark current.

7. An active pixel sensor comprising:
a photoreceptor;
a frame shutter, wherein the frame shutter is a PMOS frame shutter in a N-well; and
an active pixel readout.

8. The active pixel sensor of claim 7, wherein the photoreceptor comprises a photodiode or a photogate.

9. The active, pixel sensor of claim 7, wherein the frame shutter includes sample and hold and reset circuits.

10. The active pixel sensor of claim 9, wherein the sample and hold and reset circuits comprise NMOS transistors.

11. The active pixel sensor of claim 7, wherein the PMOS frame shutter increases the fill factor.

12. The active pixel sensor of claim 7, wherein the PMOS frame shutter reduces the pixel pitch.

13. An active pixel sensor comprising:
a photoreceptor, wherein the photoreceptor comprises a pinned photodiode;
a frame shutter, wherein the frame shutter comprises a NMOS frame shutter in a P-well; and
an active pixel readout.

14. The active pixel sensor of claim 13, wherein the frame shutter includes sample and hold and reset circuits.

15. The active pixel sensor of claim 14, wherein the sample and hold and reset circuits comprise NMOS transistors.

16. The active pixel sensor of claim 13, wherein the pinned photodiode increases the quantum efficiency.

17. The active pixel sensor of claim 13, wherein the pinned photodiode reduces dark current.

18. The active pixel sensor of claim 13, wherein the PMOS frame shutter increases the fill factor.

19. The active pixel sensor of claim 13, wherein the PMOS frame shutter reduces the pixel pitch.
